(19) United States
(12) Patent Application Publication
(10) Pub. No.: US 2017/0365482 A1
(43) Pub. Date: Dec. 21, 2017

(54) Method For Growing NI-Containing Thin Film With Single Atomic Layer Deposition Technology

(71) Applicants: INSTITUTE OF MICROELECTRONICS, CHINESE ACADEMY OF SCIENCES, Beijing (CN); JIANGNAN UNIVERSITY, Wuxi (CN)

(72) Inventors: Yuqiang DING, Wuxi (CN); Liyong DU, Wuxi (CN); Yuxiang ZHANG, Wuxi (CN); Chao ZHAO, Kessel-lo (BE); Jinjuan XIANG, Beijing (CN)

(21) Appl. No.: 15/366,499

(22) Filed: Dec. 1, 2016

(30) Foreign Application Priority Data
Jun. 15, 2016 (CN) 201610424181.X

(51) Int. Cl. H01L 21/285; C23C 16/18; C23C 16/455; H01L 21/768

(52) U.S. Cl. CPC H01L 21/28556; C23C 16/45525; C23C 16/18; H01L 21/76879

(57) ABSTRACT

The present invention provides a method for growing ni-containing thin film with single atomic layer deposition technology, comprising steps of: A) placing a substrate in a reaction chamber, and under the vacuum condition, passing a gas-phase Ni source in a form of pulses into the reaction chamber for deposition to obtain a substrate deposited with the Ni source, the Ni source comprising a compound having a structure of Formula I; B) passing a gas-phase reducing agent in a form of pulses into the reaction chamber to reduce the Ni source deposited on the substrate, obtaining a substrate deposited with a Ni thin film. The application of the Ni source having a structure of Formula I in the single atomic layer deposition technology allows a Ni-containing deposition layer with good shape retention to be deposited and formed on a nano-sized semiconductor device.

### CROSS REFERENCE OF RELATED APPLICATION

This application claims the priority of Chinese Patent Application No. 201610424181.X filed on Jun. 15, 2016 with the Chinese Patent Office, entitled “Method For Growing Ni-Containing Thin Film With Single Atomic Layer Deposition Technology”, which is incorporated in this application by reference in its entirety.

### FIELD

The present invention belongs to the field of semiconductor preparation technologies, and especially relates to a method for growing a metal Ni with a single atomic layer deposition technology.

### BACKGROUND

A Ni metal-silicide as a contact material has extensive applications in the source-drain technologies of CMOS (Complementary Metal Oxide Semiconductor) devices. As a contact metal, the Ni-silicide has outstanding advantages of such as a low resistivity, being continuous, being uniform. For all the conventional Ni-silicides, one layer of the Ni metal is deposited by a PVD (Physical Vapor Deposition) technology, and then is subjected to thermal annealing to generate a silicide by reacting the Ni with silicon.

Due to the development requirement of microelectronic and deep submicron chip technologies, the size of devices and materials is continuously reduced, and the aspect ratio in devices is continuously increased, such that the thickness of the used materials are reduced down to several nanometers. When the size of the CMOS device has continuously reduced to a technology node of 16/14 nanometers or below, there has been a large improvement on the silicide technology, which employs a technology of silicide contact later. Specifically, it is a method in which a contact hole or contact groove is firstly formed, and then a metal is deposited in the hole and groove, which method only forms a silicide when contacting with the bottom. In this case, the metal silicide formed by Ni deposition with a traditional PVD method has not meet requirements. In particular, when the silicon material in the source-drain region is Fin or a nanowire, the Ni silicide deposition layer formed by the PVD method is very difficult to form.

### SUMMARY

The present invention aims to provide a method for growing a metal Ni with a single atomic layer deposition technology, and the method of the present invention is capable of depositing and forming a Ni-containing deposition layer on a nano-sized semiconductor device.

The present invention provides a method for growing a Ni-containing thin film with a single atomic layer deposition technology, comprising steps of:

A) placing a semiconductor substrate in a reaction chamber, and under the vacuum condition, passing a gas-phase Ni source in a form of pulses into the reaction chamber for deposition to obtain a substrate deposited with the Ni source, the Ni source comprising a compound having a structure of Formula I:

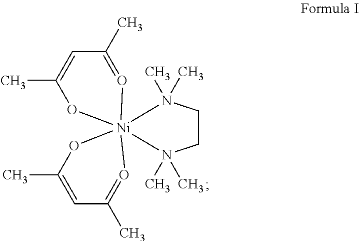

B) passing a gas-phase reducing agent in a form of pulses into the reaction chamber to reduce the Ni source deposited on the substrate, obtaining a substrate deposited with a Ni thin film.

Preferably, a single pulse in passing the gas-phase Ni source in the form of pulses into the reaction chamber in the step A) has a duration of 0.05˜20 s.

Preferably, an interval time between two pulses in the step A) is 0.5˜30 s.

Preferably, the deposition in the step A) is at a temperature of 125˜400° C.

Preferably, the gas-phase Ni source is passed in the form of pulses in the presence of a carrier gas;

the carrier gas has a flow rate of 10˜200 sccm.

Preferably, the gas-phase reducing agent in the step B) comprises one or several of H₂, NH₃, B₂H₆, monoalkylboranes, aminoboranes, alcohols, hydrazines, alkyl aluminiums, amino alkyl aluminiums and alkyl zincs.

Preferably, a single pulse in passing the gas-phase reducing agent in the form of pulses into the reaction chamber in the step B) has a duration of 0.01˜20 s.

Preferably, an interval time between two pulses in the step B) is 0.5˜30 s.

Preferably, the gas-phase reducing agent is passed in the form of pulses in the presence of a carrier gas;

the carrier gas has a flow rate of 10˜200 sccm.

Preferably, the semiconductor substrate comprises one or several of silicon, silicon oxide, silicon nitride, TaN and sapphire.

The present invention provides a method for growing a Ni-containing thin film with a single atomic layer deposition technology, comprising steps of: A) placing a substrate in a reaction chamber, and passing a gas-phase Ni source in a form of pulses into the reaction chamber under the vacuum condition for deposition to obtain a substrate deposited with the Ni source, the Ni source comprising a compound having a structure of Formula I; B) passing a gas-phase reducing agent in a form of pulses into the reaction chamber to reduce the Ni source deposited on the substrate, obtaining a substrate deposited with a Ni thin film. In the present invention, application of the Ni source having a structure of Formula I in the single atomic layer deposition technology allows a Ni-containing deposition layer with good shape retention to be deposited and formed on a nano-sized semiconductor device. The Ni source (Ni(acac)₂(TMEDA)) has good volatility, a high thermal decomposition temperature and a low cost, and thus is capable of being suitable for a single atomic layer deposition (ALD) process at high temperature, to obtain a Ni-containing deposition layer with good shape retention (shape preserving or conformality). Moreover, the Ni film made using the method of the present invention has lower electrical conductivity, and results show that, the Ni thin film made in the present invention has a resistivity in a range of 13˜24 μΩ·cm.

### BRIEF DESCRIPTION OF THE DRAWINGS

In order to more clearly illustrate examples of the present invention or technical solutions in the prior art, figures needed for use in the examples or the prior art will be simply introduced hereinafter. Obviously, the figures in the following description is merely for examples of the present invention and for those skilled in the art, other figures can be obtained according to the figures as provided without any creative work.

FIG. 1 is a thermal decomposition diagram for Ni(acac)₂(TMEDA), NiCp₂ and Ni(acac)₂.

FIG. 2 is a SEM image for the Ni thin film in Example 1 of the present invention.

### DETAILED DESCRIPTION

The present invention provides a method for growing a Ni-containing thin film with a single atomic layer deposition technology, comprising steps of:

A) placing a substrate in a reaction chamber, and under the vacuum condition, passing a gas-phase Ni source in a form of pulses into the reaction chamber for deposition to obtain a substrate deposited with the Ni source, the Ni source comprising a compound having a structure of Formula I:

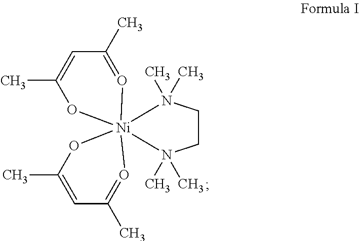

B) passing a gas-phase reducing agent in a form of pulses into the reaction chamber to reduce the Ni source deposited on the substrate, obtaining a substrate deposited with a Ni thin film.

For the placing a substrate in a reaction chamber, and passing a gas-phase Ni source in a form of pulses into the reaction chamber under the vacuum condition for deposition to obtain a substrate deposited with the Ni source. In the present invention, it is preferred in the present invention that the substrate which needs to be deposited with a Ni-containing thin film is firstly cleaned to obtain a pretreated substrate. In the present invention, standard cleaning in industry is preferably used, for example, removing organic contaminations on the substrate surface using a SPM(H₂SO₄/H₂O₂) solution, removing particle contaminations using a APM(NH₄OH/H₂O₂) solution, removing a naturally oxidized layer by rinsing the substrate with a diluted HF solution. In actual applications, it is not limited to such cleaning methods, and other cleaning methods can be used depending on the actual application, such as acetone-isopropanol cleaning, etc.

After the pretreated substrate is obtained, it is preferred in the present invention that the pretreated substrate is placed into a transfer chamber of an atomic layer deposition device achieving a vacuum environment necessary to deposition, and then transferred into a reaction chamber after the required vacuum level is reached, to avoid diffusion of the water-dissolved oxygen in the air into the reaction chamber influencing the growing of the metal film. In order to further ensure no water-dissolved oxygen residue in each pipeline and chamber of the atomic layer deposition device, prior to placing the substrate, it is preferred in the present invention to subject the pipeline and chamber of the atomic layer deposition device to evacuation or treatment with film pre-growing.

In the present invention, the substrate preferably comprises one or several of silicon, silicon oxide, silicon nitride, TaN and sapphire; the gas-phase Ni source comprises a compound having a structure of Formula I, which has a chemical formula of Ni(acac)₂(TMEDA). The source of the Ni source compound having a structure of Formula I has no particular limitation, and can be synthesized in accordance with the document Journal of Organometailic Chemistry, 355 (1988) 525-532.

In the present invention, it is preferred to heat the Ni source for gasification to obtain the gas-phase Ni source, wherein the temperature to which the Ni source is heated is preferably 25˜300° C., more preferably 50˜180° C., and specifically may be 90° C., 120° C., 150° C. or 180° C.

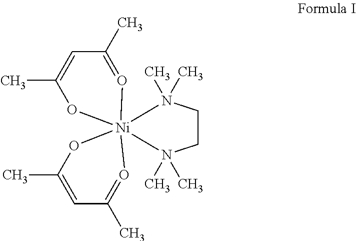

Ni(acac)₂(TMEDA) has the following advantages compared to conventional Ni sources such as Nickelocene NiCp₂ and acetylacetonate nickel Ni(acac)₂, in which:

(1) it has a volatility which is similar with NiCp₂ and obviously superior to Ni(acac)₂, and the costs far less than NiCp₂;

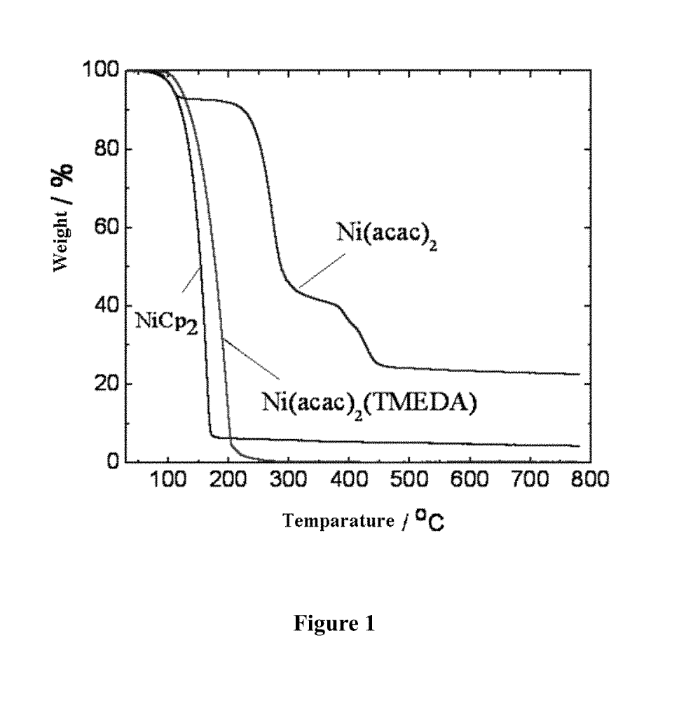

(2) its thermal decomposition temperature is far higher than Ni(acac)₂, by reference to FIG. 1 which is a thermal decomposition diagram for Ni(acac)₂(TMEDA), NiCp₂ and Ni(acac)₂. As can be seen from FIG. 1, Ni(acac)₂ is decomposed at 120° C., NiCp₂ is decomposed at 172° C., and Ni(acac)₂(TMEDA) of the present application is decomposed at higher than 300° C. (it is tested that the Ni(acac)₂(TMEDA) is not decomposed at 300° C.); therefore, Ni(acac)₂(TMEDA) is capable of being suitable for a ALD process at a high temperature.

(3) it has low sensitivity to air humidity, and is easy to store and transport.

In the present invention, a single pulse of the gas-phase Ni source has a duration of preferably 0.05˜20 s, more preferably 1˜18 s, most preferably 3˜15 s, which specifically in examples of the present invention may be 1 s, 5 s, 8 s, 12 s or 16 s. An interval time between two pulses of the gas-phase Ni source is preferably 0.5˜30 s, more preferably 1˜25 s, most preferably 5˜20 s, which specifically in examples of the present invention may be 5 s, 10 s, 15 s, 20 s or 25 s. The deposition is preferably at a temperature of 125˜400° C., more preferably 150˜350° C., most preferably 200˜300° C., which specifically in examples of the present invention may be 150° C., 200° C., 250° C., 300° C. or 350° C. The carrier gas of the gas-phase Ni source is preferably high-purity nitrogen or high-purity argon, and the carrier gas has a flow rate of preferably 10˜200 sccm, more preferably 20˜160 sccm, most preferably 60˜120 sccm, which specifically may be 20 sccm, 90 sccm, 120 sccm, 160 sccm or 60 sccm.

After the first deposition of the Ni source is completed, it is preferred in the present invention that the reaction chamber is purged and cleaned with the high-purity nitrogen or high-purity argon for a cleaning duration of preferably 5˜50 s, more preferably 10˜45 s, most preferably 15˜40 s.

Afterwards, in the present invention, a gas-phase reducing agent is passed into the reaction chamber to reduce the Ni source deposited on the substrate, to obtain a substrate deposited with a Ni thin film, wherein in the present invention, the reducing agent preferably comprises one or several of H₂, NH₃, B₂H₆, monoalkylboranes, aminoboranes, alcohols, hydrazines, alkyl aluminiums, amino alkyl aluminiums and alkyl zincs, and more preferably comprises one or several of H₂, NH₃, B₂H₆, monoalkylboranes (R₁BH₂ or R₁R₂BH), aminoboranes (R₁R₂HN.BH₃ or R₁R₂R₃N.BH₃), alcohols (R₁OH), hydrazines (R₁NHNH₂ or N₂H₄), alkyl aluminiums (AlR₁R₂R₃), amino alkyl aluminiums (R₁R₂R₃N.AlH₃) and alkyl zincs (ZnR₁R₂) in which R₁, R₂, R₃ are C1˜C10 hydrocarbyl groups and may be identical or different from each other, and R₁ in different compounds may be identical or different, for example, the R₁ in R₁OH and R₁NHNH₂ may be identical or different. Specifically, in examples of the present invention, as the reducing agent, N₂H₄, Me₂NH.BH₃, CH₃OH, AlMe₃ or ZnEt₂ can be used. It is preferred in the present invention to heat the reducing agent for gasification to form a gaseous reducing agent. The temperature to which the reducing agent is heated is preferably 25˜150° C., more preferably 40˜140° C., which specifically in examples of the present invention may be 60° C., 90° C., 20° C. or 85° C.

In the present invention, a single pulse of passing the reducing agent has a duration of preferably 0.01˜20 s, more preferably 1˜15 s, more preferably 5˜10 s, which specifically in examples of the present invention may be 10 s, 1 s, 20 s, 15 s or 5 s. An interval time between two pulses of passing the reducing agent is preferably 0.5˜30 s, more preferably 1˜25 s, most preferably 5˜20 s, which specifically in examples of the present invention may be 15 s, 5 s, 10 s, 25 s or 20 s. The carrier gas of the gas-phase reducing agent is preferably high-purity nitrogen or high-purity argon, and the carrier gas has a flow rate of preferably 10˜200 sccm, more preferably 20˜160 sccm, most preferably 60˜120 sccm.

After the first reduction is completed, it is preferred in the present invention that the reaction chamber is purged and cleaned with the high-purity nitrogen or high-purity argon for a cleaning duration of preferably 5˜50 s, more preferably 10˜45 s, most preferably 15˜40 s.

In the present invention, it is preferred to repeat such a process as described above: gas-phase Ni source deposition—purge and cleaning—reduction with gas phase reducing agent-purge and cleaning, with the number of the repeated cycles depending on actual requirements, which in the present invention is preferably 300˜4500, more preferably 1000˜3000, and specifically in examples of the present invention may be 300, 1000, 1500, 3000 or 4500.

The method of the present invention is not only suitable for preparation of a metal Ni thin film material by using a compound Ni(acac)₂(TMEDA) having a structure of Formula I alone as a Ni source precursor, but also can be combined with other materials for the growing of thin films of Ni oxides, Ni nitrides or Ni alloys.

The method for growing a Ni-containing thin film with a single atomic layer deposition (ALD) technology provided in the present invention having the following advantages:

(1) The Ni source precursor Ni(acac)₂(TMEDA) has a volatility which is similar with NiCp₂ and much superior to Ni(acac)₂, and costs far less than NiCp₂; and it has a thermal decomposition temperature which is far higher than Ni(acac)₂. Therefore, Ni(acac)₂(TMEDA) is capable of being suitable for a ALD process at a high temperature; and it has low sensitivity to air humidity, and is easy to store and transport.

(2) Ni(acac)₂(TMEDA) is capable of forming a film with various liquid reducing agents, and is more convenient and safer relative to H₂ or NH₃ as reported currently.

(3) The as-prepared Ni film has a lower resistivity.
(4) It exhibits good compatibility with various substrates such as silicon, silicon oxide, silicon nitride, TaN, sapphire and the like.

In order to further illustrate the present invention, the method for growing a Ni-containing thin film with a single atomic layer deposition technology provided in the present invention is described in detail hereinafter in conjunction with examples, which are not to be construed as limiting the protection scope of the present invention.

### Example 1

A deposition method for a Ni thin film atomic layer with Ni(acac)₂(TMEDA) as the Ni source and N₂H₄ as a reducing agent comprises the following process.

1) Si was used as a substrate, and was deposited at a temperature of 250° C.; the Ni source Ni(acac)₂(TMEDA) was heated to a temperature of 90° C. for gasification, and a gas-phase Ni source Ni(acac)₂(TMEDA) was supplied with high-purity nitrogen as a carrier gas at a flow rate of 20 sccm. The duration of pulses was 12 s, and the waiting time was 10 s.

2) After one pulse, it was cleaned with high-purity nitrogen for a cleaning duration of 25 s.

3) The reducing agent N₂H₄ was heated to a temperature of 60° C. for gasification, and supplied in a form of pulses with high-purity nitrogen as a carrier at a flow rate of 60 sccm. The duration of the pulses was 5 s, and the waiting time was 15 s.

4) After one pulse of the reducing agent, it was cleaned with high-purity nitrogen for a cleaning duration of 15 s.

The above steps 1)˜4) were repeated for 300 times, and the obtained Ni thin film had a thickness of 9 nm, and a resistivity of 24 μΩ·cm as tested with a four-probe method.

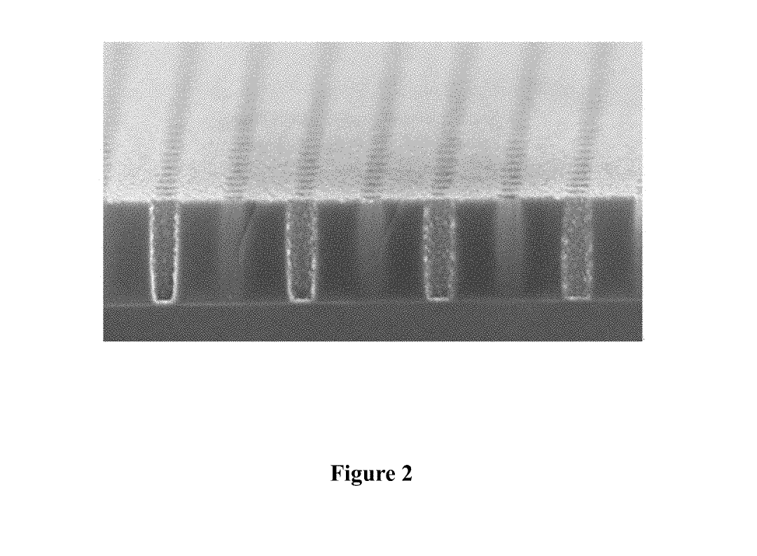

The Ni thin film obtained in this example was subjected to a scanning electron microscopy test in the present invention, with results as shown in FIG. 2. FIG. 2 is a SEM image for the Ni thin film in Example 1 of the present invention, from which it can be seen that, the Ni thin film obtained in this example has good shape retention.

### Example 2

A deposition method for a Ni thin film atomic layer with Ni(acac)₂(TMEDA) as a Ni source and Me₂NH.BH₃ as a reducing agent comprises the following process.

1) SiO₂ was used as a substrate, and was deposited at a temperature of 300° C.; the Ni source Ni(acac)₂(TMEDA) was heated to a temperature of 150° C. for gasification, and a gas-phase Ni source Ni(acac)₂(TMEDA) was supplied with high-purity argon as a carrier gas at a flow rate of 90 sccm. The duration of pulses was 5 s, and the waiting time was 20 s.

2) After one pulse, cleaning with high-purity argon for a cleaning duration of 45 s.

3) The reducing agent Me₂NH.BH₃ was heated to a temperature of 90° C. for gasification, and supplied in a form of pulses with high-purity argon as a carrier at a flow rate of 10 sccm. The duration of the pulses was 15 s, and the waiting time was 5 s.

4) After one pulse of the reducing agent, it was cleaned with high-purity nitrogen for a cleaning duration of 35 s.

The above steps 1)˜4) were repeated for 1000 times, and the obtained Ni thin film had a thickness of 17 nm, and a resistivity of 15 μΩ·cm as tested with a four-probe method.

### Example 3

A deposition method for a Ni thin film atomic layer with Ni(acac)₂(TMEDA) as a Ni source and CH₃OH as a reducing agent comprises the following process.

1) Silicon nitride was used as a substrate, and was deposited at a temperature of 350° C.; the Ni source Ni(acac)₂(TMEDA) was heated to a temperature of 120° C. for gasification, and a gas-phase Ni source Ni(acac)₂(TMEDA) was supplied with high-purity argon as a carrier gas at a flow rate of 120 sccm. The duration of pulses was 8 s, and the waiting time was 5 s.

2) After one pulse, it was cleaned with high-purity argon for a cleaning duration of 15 S.

3) The reducing agent CH₃OH was heated to a temperature of 25° C. for gasification, and supplied in a form of pulses with high-purity argon as a carrier at a flow rate of 160 sccm. The duration of the pulses was 20 s, and the waiting time was 10 s.

4) After one pulse of the reducing agent, it was cleaned with high-purity nitrogen for a cleaning duration of 5 s.

The above steps 1)˜4) were repeated for 3000 times, and the obtained Ni thin film had a thickness of 19 nm, and a resistivity of 13 μΩ·cm as tested with a four-probe method.

### Example 4

A deposition method for a Ni thin film atomic layer with Ni(acac)₂(TMEDA) as a Ni source and AlMe₃ as a reducing agent comprises the following process.

1) Sapphire was used as a substrate, and was deposited at a temperature of 150° C.; the Ni source Ni(acac)₂(TMEDA) was heated to a temperature of 60° C. for gasification, and a gas-phase Ni source Ni(acac)₂(TMEDA) was supplied with high-purity nitrogen as a carrier gas at a flow rate of 160 sccm. The duration of pulses was 16 s, and the waiting time was 25 s.

2) After one pulse, it was cleaned with high-purity nitrogen for a cleaning duration of 10 s.

3) The reducing agent AlMe₃ was heated to a temperature of 60° C. for gasification, and AlMe₃ is supplied in a form of pulses with high-purity nitrogen as a carrier at a flow rate of 120 sccm. The duration of the pulses was 1 s, and the waiting time was 25 s.

4) After one pulse of the reducing agent, it was cleaned with high-purity nitrogen for a cleaning duration of 45 s.

The above steps 1)˜4) were repeated for 4500 times, and the obtained Ni thin film had a thickness of 20 nm, and a resistivity of 19 μΩ·cm as tested with a four-probe method.

### Example 5

A deposition method for a Ni thin film atomic layer with Ni(acac)₂(TMEDA) as a Ni source and ZnEt₂ as a reducing agent comprises the following process.

1) TaN was used as a substrate, and was deposited at a temperature of 200° C.; the Ni source Ni(acac)₂(TMEDA) was heated to a temperature of 180° C. for gasification, and a gas-phase Ni source Ni(acac)₂(TMEDA) was supplied with high-purity nitrogen as a carrier gas at a flow rate of 60 sccm. The duration of pulses was 1 s, and the waiting time was 15 s.

2) After one pulse, it was cleaned with high-purity nitrogen for a cleaning duration of 35 s.

3) The reducing agent ZnEt₂ was heated to a temperature of 850° C. for gasification, and ZnEt₂ is supplied in a form of pulses with high-purity nitrogen as a carrier at a flow rate of 90 sccm. The duration of the pulses was 10 s, and the waiting time was 20 s.

4) After one pulse of the reducing agent, it was cleaned with high-purity nitrogen for a cleaning duration of 25 s.

The above steps 1)˜4) were repeated for 1500 times, and the obtained Ni thin film had a thickness of 16 nm, and a resistivity of 14 μΩ·cm as tested with a four-probe method.

The foregoing description is only for preferred embodiments of the present invention, and it is to be indicated that, for those skilled in the art, several improvements and modifications can be made without departing from the principle of the present invention, which improvements and modifications are deemed to fall within the protection scope of the present invention.

1. A method for growing a Ni-containing thin film with a single atomic layer deposition technology, comprising steps of:
A) placing a semiconductor substrate in a reaction chamber, and passing a gas-phase Ni source in a form of pulses into the reaction chamber for deposition under the vacuum condition to obtain a substrate deposited with the Ni source, the Ni source comprising a compound having a structure of Formula I: 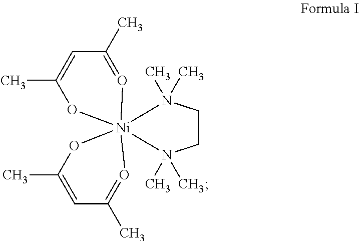
B) passing a gas-phase reducing agent in a form of pulses into the reaction chamber to reduce the Ni source deposited on the substrate, to obtain a substrate deposited with a Ni thin film.

2. The method according to claim 1, wherein a single pulse in supplying the gas-phase Ni source in the form of pulses into the reaction chamber in the step A) has a duration of 0.05˜20 s.

3. The method according to claim 2, wherein an interval time between two pulses in the step A) is 0.5˜30 s.

4. The method according to claim 1, wherein the deposition in the step A) is at a temperature of 125˜400° C.

5. The method according to claim 1, wherein the gas-phase Ni source is passed in the form of pulses in the presence of a carrier gas;
the carrier gas has a flow rate of 10˜200 sccm.

6. The method according to claim 1, wherein the gas-phase reducing agent in the step B) comprises one or several of H₂, NH₃, B₂H₆, monoalkylboranes, aminoboranes, alcohols, hydrazines, alkyl aluminiums, amino aluminum hydride and alkyl zincs.

7. The method according to claim 1, wherein, in the step B), a single pulse in passing the gas-phase reducing agent in the form of pulses into the reaction chamber has a duration of 0.01˜20 s.

8. The method according to claim 7, wherein, in the step B), an interval time between two pulses is 0.5˜30 s.

9. The method according to claim 1, wherein the gas-phase reducing agent is supplied in the form of pulses in the presence of a carrier gas;
the carrier gas has a flow rate of 10˜200 sccm.

10. The method according to claim 1, wherein the semiconductor substrate comprises one or several of silicon, silicon oxide, silicon nitride, TaN and sapphire.
